(19) United States
(12) Patent Application Publication
(10) Pub. No.: US 2023/0084463 A1
(43) Pub. Date: Mar. 16, 2023

(54) RUNTIME NON-DESTRUCTIVE MEMORY BUILT-IN SELF-TEST (BIST)

(71) Applicant: Intel Corporation, Santa Clara, CA (US)

(72) Inventors: Sreejit CHAKRAVARTY, San Jose, CA (US); Rakesh KANDULA, Bangalore (IN); Deep BAROT, Mumbai (IN); Vishal VENDE, Bangalore (IN)

(21) Appl. No.: 17/989,951

(22) Filed: Nov. 18, 2022

(51) Int. Cl. G06F 3/06; G11C 29/12

(52) U.S. Cl. CPC G06F 3/0617; G06F 3/0673; G06F 3/0629; G11C 29/12

(57) ABSTRACT

Runtime memory BIST techniques are described herein. In one example, a system such as an SoC includes logic to schedule runtime testing of the memory that is non-destructive in multiple phases. Running testing of memory in multiple phases includes triggering a memory built-in self-test (BIST) testing of a subset of memory locations in a phase, where the processing logic is to pause access to the memory during the phase. The processing logic can resume access to the memory between testing phases. The next region of the memory can be tested in the phase that follows. This process can continue until the entire memory is tested, without requiring the system to be powered down.

### FIELD

Descriptions are generally related to memory testing, such as runtime memory BIST testing that is non-destructive.

### BACKGROUND

Computer systems include one or more types of memory to store both user data and instructions for execution by a processor. Memory can be susceptible to errors due to a variety of reasons. Some errors are detectable via error detection and/or correction schemes. However, other errors, referred to as silent data errors, go undetected by the system. Silent data errors can result in data corruption and system failure. Silent data errors can be caused by a variety of factors, including particle-strike or aging. Regardless of the source of silent data errors, silent data errors can cause significant problems in computing platforms such as systems on a chip (SoCs) used in data centers, by cloud service providers (CSPs) and in other high-performance computing applications. Silent data errors can also result in safety issues in automotive systems.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” or examples are to be understood as describing a particular feature, structure, and/or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 is a Venn diagram illustrating an example of errors detected with different error detection techniques.

FIG. 2 is a block diagram illustrating an example of a system including runtime array BIST scheduling logic.

FIG. 3A is a block diagram of an example of a system including runtime array BIST scheduling logic.

FIG. 3B is a block diagram of an example of an array BIST scheduler.

FIG. 3C is a block diagram of an example of runtime array BIST configuration registers.

FIG. 4 illustrates an example of phases in which subsets of memory locations can be tested with memory BIST.

FIG. 5 is a flow chart of an example of a method of testing a memory during runtime with memory BIST.

FIG. 6 illustrates a timing diagram of handshaking signals for runtime array BIST testing.

FIG. 7 illustrates a block diagram of an example of an SoC in which runtime array BIST can be implemented.

FIG. 8 illustrates a block diagram of an exemplary compute platform in which embodiments described and illustrated herein may be implemented.

Descriptions of certain details and implementations follow, including a description of the figures, which may depict some or all of the embodiments described below, as well as discussing other potential embodiments or implementations of the inventive concepts presented herein.

### DETAILED DESCRIPTION

Memory testing techniques are described herein that can enable detection of memory defects before they result in silent data errors (SDEs).

Existing hardware approaches to address silent data errors and functional safety problems pertaining to defects in memories include the use of ECC or parity protection on the address and data buses, and the use of power-on-self tests (POST) for memories. Although ECC and parity protection can mitigate some errors, ECC and parity protection cannot protect memories from all error sources, such as permanent failures arising from aging of the silicon. Furthermore, ECC protection can be very expensive to implement, especially address bit protection. For example, adding one bit of parity on the address bus for a cache can result in a significant area increase for the cache. Power-on-self test can be effective at detecting errors, however, requires bringing down the system, running an exhaustive memory test using memory BIST (built-in self-test) and rebooting the system. For data centers, performing POST is typically only feasible when an SoC is initially powered up. Typically, the un-core part of servers cannot be powered down or taken offline for POST to be applied frequently enough to effectively prevent silent data errors.

In contrast, the memory testing techniques described herein can detect errors during runtime without requiring a system to be brought down and without being prohibitively expensive in terms of SoC area. In one example, a device includes logic to periodically schedule memory BIST testing of a memory during runtime, including to request, during runtime, that a functional unit or processing logic pause access to the memory. In one example, the logic then causes a memory BIST controller to test a subset of memory locations of the memory while access to the memory is paused. After the subset of memory locations is tested, the logic sends a notification to the functional unit or processing logic to resume access to the memory. Thus, functional operation is paused for a small number of clock cycles while a subset of memory locations is tested. The process can be repeated over multiple phases or “micro pauses” with a small number of memory locations tested in each phase until the entire memory is tested. The test can repeat indefinitely while the system is running to detect errors and avoid user data corruption.

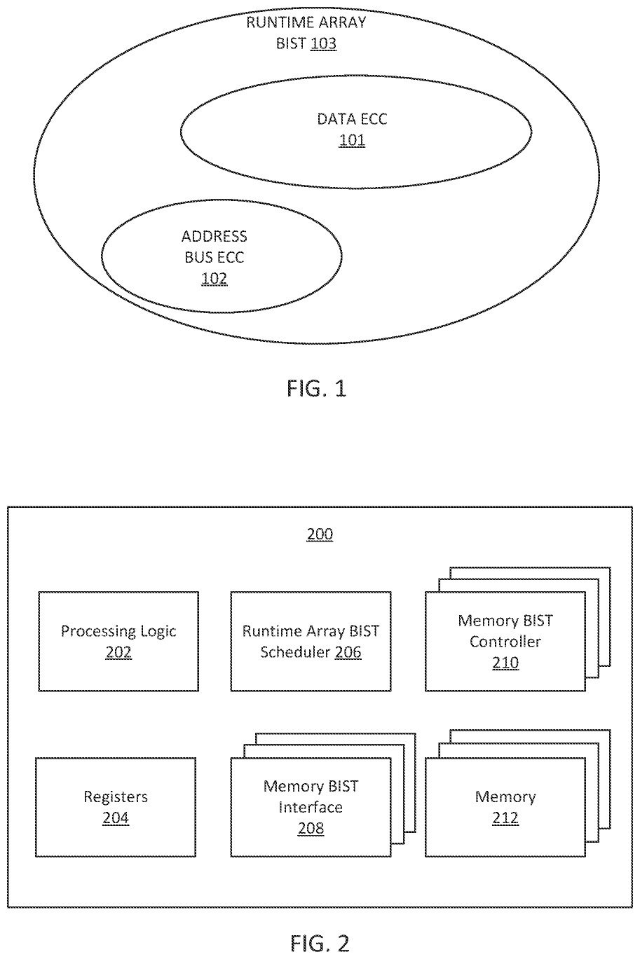

The techniques described herein can cover gaps left by data ECC (e.g., where data bit cells are ECC protected) and address bus ECC. FIG. 1 is a Venn diagram illustrating an example of errors or escapes prevented by data ECC (area 101) and address bus ECC (area 102). The runtime array BIST techniques described herein can enable preventing errors caught by data ECC, address decoder defects covered by address bus ECC, in addition to other errors that would not have been caught by data and address bus ECC alone. Thus, runtime array BIST techniques can enable wider coverage (area 103) that is comprehensive and expands beyond the coverage provided by other memory protection schemes. For products used in automotive and industrial systems, the techniques described herein can help improve functional safety, as described in the automotive safety integrity level (ASIL) and safety integrity level (SIL) standards.

FIG. 2 is a block diagram illustrating an example of a system including runtime array BIST scheduling logic. The system 200 is an example of a computing system such as an SoC, Application specific integrated circuit (ASIC), or other computing system. The components of the system 200 can be in a single package or multiple packages. The system 200 includes processing logic 202, which may include a processor (e.g., CPU, infrastructure processing unit (IPU), graphics processing unit (GPU), or other processor), a processor core, a memory controller (e.g., an integrated memory controller (iMC)), a cache controller, an accelerator, a combination thereof, and/or other processing logic or functional unit that accesses a memory 212. In one example, the memory 212 includes embedded memory and/or a cache. The system 200 can include many embedded memories, which can be of different sizes and types, For example, the memory 212 can be embedded DRAM, embedded SRAM, or other memory device or memory module.

The system 200 includes one or more memory BIST controllers 210 to control and execute BIST testing of the memory 212. A given memory BIST controller 210 can control the testing of one or multiple memories 212. According to one example, the memory BIST controller 210 includes or interfaces with logic to apply test patterns to locations in the memory 212, reading the memory locations, and comparing the applied test patterns with the data read from the memory locations. If the read data does not match the applied test pattern, an error is triggered and reported.

The system 200 includes one or more memory BIST interfaces 208. In one example, the memory BIST interfaces 208 include interface circuitry to provide a path to, and enable access to, the memory BIST controller 210. A memory BIST interface 208 can provide access to one or multiple memory BIST controllers 210.

The system includes a runtime array BIST scheduler 206 (which may also be referred to as a runtime memory BIST scheduler, or array BIST scheduler in-field (ABSI)). The array BIST scheduler 206 includes logic to schedule runtime memory BIST testing (also referred to herein as array BIST testing) of subsets of memory locations of the memory 212 during periodic micro pauses of the processing logic 202. In the example illustrated in FIG. 2, the system 200 also includes registers 204. The registers 204 can include mode registers or configuration registers to enable adjusting configuration parameters of the runtime array BIST testing or other parameters. One or more registers can be included in the runtime array BIST scheduler 206, or external to the scheduler 206 in the system 200.

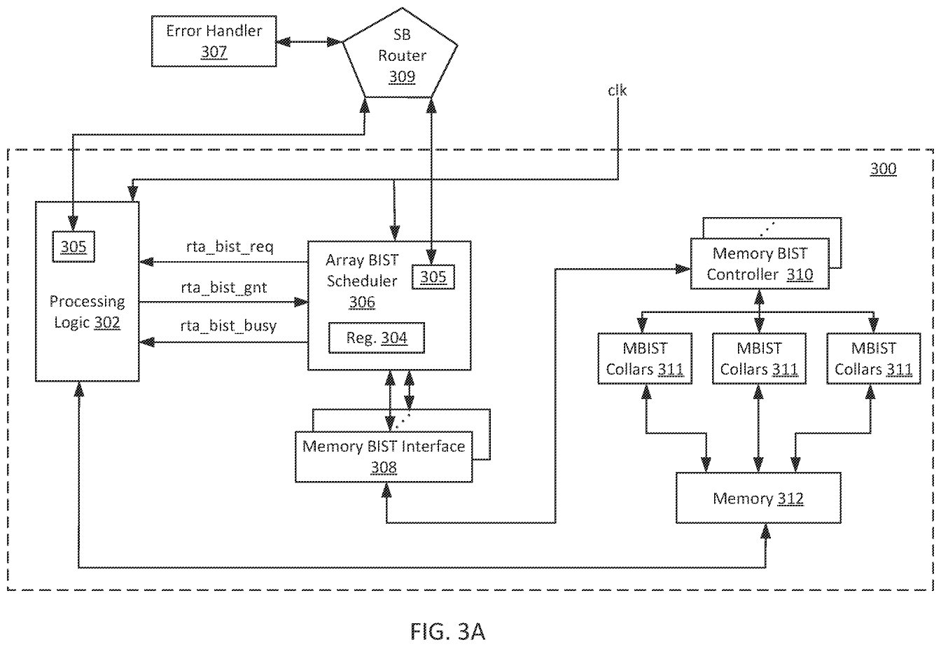

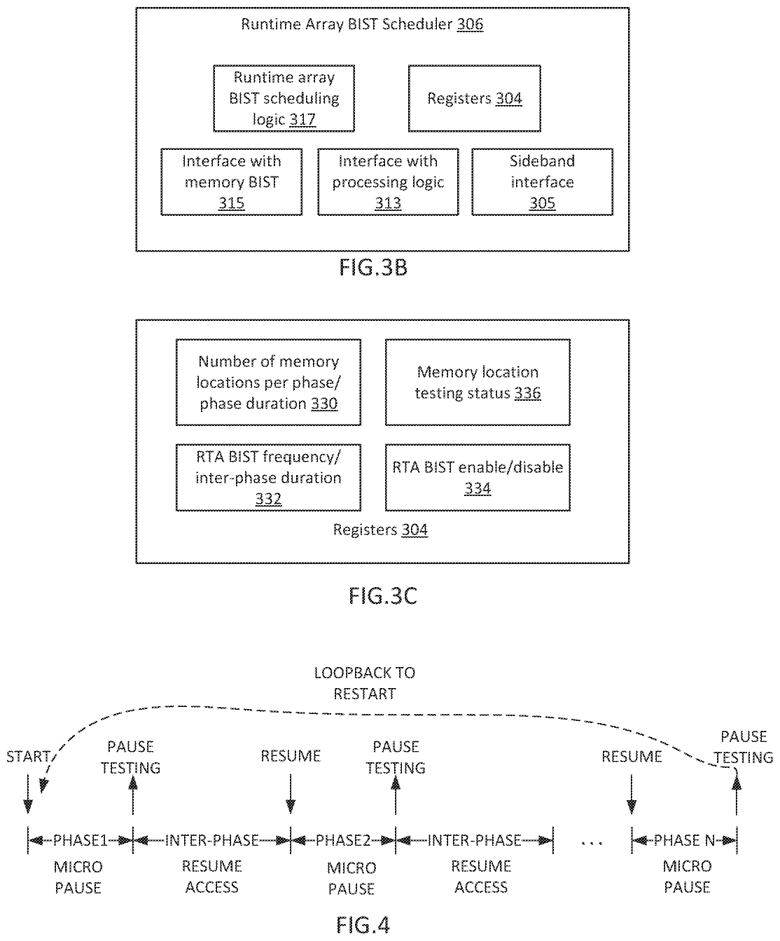

FIG. 3A is a block diagram of an example of a system including runtime array BIST scheduling logic. The system 300 is an example of the system 200 of FIG. 2. In one example, the system 300 is an SoC. Like the system 200 of FIG. 2, the system 300 includes processing logic 302, which can be the same as the processing logic 202 of FIG. 2. The system 300 also includes memory 312 coupled with the processing logic 302. The memory 312 can be the same as the memory 212 of FIG. 2 (e.g., embedded memory or other memory). Although a single box is shown for memory 312, the system 300 can include multiple memories 312, including different types and sizes of memories. Similarly, although a single box is shown for the processing logic 302, the system 300 can include multiple instances of processing logic of varying types. In one example, the processing logic 302 is coupled with the memory 312 via interface circuitry and one or more signal lines (e.g., a link, bus, or other conductive lines to couple the processing logic 302 with the memory 312). The processing logic 302 accesses memory 312 by reading data followed by writing data to memory locations of the memory 312 (e.g., locations assigned an address or addresses to enable access of memory cells of the memory 312). In one example, during runtime and during normal operation, the processing logic 302 sends commands or requests to the memory 312 to access the memory locations, such as read commands and write commands.

The system 300 also includes built-in self-test logic (e.g., circuitry and or firmware) to perform testing of the memory 312. For example, a memory BIST controller 310 is coupled with the memory 312 via memory BIST collars 311. In one example, the memory BIST collars include logic to apply patterns or sequences to the memory 312. In one such example, the memory BIST collars 311 include a wrapper around the memory 312 that provides a path for the memory BIST controller 310 to access the memory 312. In one example, the memory BIST collars 311 include one or more state machines, scan chains, or other logic implemented in hardware to apply predetermined patterns to the memory 312. In one such example, a scan chain includes a series of flip flops configured as a shift register. In one example, the memory BIST controller 310 includes or interfaces with one or more scan chains for input data and addresses and one or more scan chains for output data read from the memory 312. The memory BIST controller 310 can then compare the applied test patterns with the data read from the memory locations of the memory 312. In one example, if the read data does not match the expected value (e.g., an applied test pattern), an error is triggered and reported. Like the memory BIST controller 210 of FIG. 2, a given memory BIST controller 310 can control the testing of one or multiple memories 312.

The system 300 includes an array BIST scheduler 306. FIG. 3B is a block diagram of the array BIST scheduler 306, in accordance with one example. The array BIST scheduler 306 includes an interface to communicate with the processing logic 302 (e.g., the interface 313), an interface to communicate with the memory BIST infrastructure (e.g., the memory BIST interface 315), and an interface to communicate with an error handler (e.g., the sideband interface 305 or any other interface with a bus or link, such as an interface to an Advanced eXtensible Interface (AXI) bus, advanced peripheral bus (APB), or other functional interface to couple the array BIST scheduler 306 with an error handler).

In one example, the array BIST scheduler 306 includes logic 317 that schedules runtime testing of the memory 312 in multiple phases when the processing logic pauses access to the memory 312. In one such example, the array BIST scheduler requests that the processing logic 302 pause access to the memory 312 for a predetermined number of clock cycles in order to test a small portion of the memory 312 with memory BIST. The processing logic 302 agrees to pause or suspend access to the memory 312 for a predetermined time and/or until the array BIST scheduler 306 notifies the processing logic that memory BIST testing has completed. In one such example, the array BIST scheduler 306 and the processing logic 302 can communicate via an interface including handshaking signal lines, such as the rta_bist_req (runtime array BIST request), rta_bist_gnt (runtime array BIST grant), and rta_bist_busy (runtime array BIST busy) signal lines between the processing logic 302 and the array BIST scheduler 306. Thus, in one example, the array BIST scheduler 306 uses its interface with the processing logic 302 to request pause-intervals to run one phase of the memory test.

The system 300 includes one or more memory BIST interfaces 308 to couple the array BIST scheduler 306 with one or more memory BIST controllers 310. In one example, the memory BIST interfaces 308 include interface circuitry to provide a path to, and enable access to, the memory BIST controller 310. A memory BIST interface 308 can provide access to one or multiple memory BIST controllers 310. Thus, the system 300 can include multiple instances of the memory BIST access tree (e.g., an interface 308 and signal lines coupled with one or more controller 310) to enable access to the memory BIST testing circuitry, such as the memory BIST controller 310. In one example, the memory BIST interface 308 is used by the array BIST scheduler 306 for control of the phased execution of memory BIST. For example, the array BIST scheduler 306 can control the test algorithm to be executed, start and pause one phase of the memory test, and receive error reporting via the memory BIST interface 308. In one such example, the memory BIST controller 310 supports the pause and resume requests, along with the non-destructive property of the memory test. In one example, non-destructive testing is performed by saving the content of a small number of memory locations, testing those locations, and restoring the content of those locations.

The system 300 includes registers 304. The registers 304 can include mode registers or configuration registers to enable adjusting configuration parameters of runtime array BIST testing or other parameters. The registers 304 can be the same as the registers 204 described above with respect to FIG. 2. FIG. 3C illustrates a block diagram of an example of runtime array BIST configuration registers. The registers 304 include different registers and/or different fields or ranges of the same register(s). The registers 304 of FIG. 3C include a register 330 or field to indicate a number of memory locations per phase (e.g., the number of memory locations in a subset to be tested in a given phase or micropause) and/or the duration of a phase. The registers 304 of FIG. 3C also include a register 332 or field to indicate the frequency of runtime array BIST testing and/or the duration of an inter-phase (e.g., how many clock cycles are to pass after completion of a testing phase before the array BIST scheduler requests the next micro pause to test the next subset of memory locations).

In one example, the registers 304 of FIG. 3C include a register 336 or field to track testing status. For example, the runtime array BIST scheduler 306 keeps track of which memory location(s) have been tested and/or which memory location(s) are to be tested next. For example, the register 336 can store or indicate a pointer (e.g., address) of one or more memory locations of the memory 312 to enable the runtime array BIST scheduler 306 to determine which memory locations to test next in order to eventually test all memory locations of the memory 312. The registers 304 may also include a register 334 to indicate that runtime array BIST is enabled or disabled. Other or different registers or fields may also be included to enable configuration or execution of runtime array BIST testing. In one such example, one or more “start” bits can trigger the initial runtime array BIST testing and/or one or more “stop” bits can trigger stopping runtime array BIST testing. In other examples, the enable/disable register bit(s) can be used to start and stop runtime array BIST. In another example, the runtime array BIST testing happens automatically during runtime as long as runtime array BIST is enabled.

Referring again to FIG. 3A, after completion of memory BIST for a subset of memory locations of the memory 312, the array BIST scheduler 306 can receive notification of errors from the memory BIST controller 312 that were detected while testing the current subset of memory locations. The array BIST scheduler 306 can then report the errors to an error handler 307. In one example, the array BIST scheduler has a sideband interface logic 305 with a sideband router 309, via which errors can be communicated to the error handler 307. In one such example, the sideband interface logic 305 includes or is a sideband endpoint or access point. In the example of FIG. 3A, the processing logic 302 also includes a sideband interface 305. In one example, the error handler 307 includes logic to receive and/or log errors. In one example, the error handler 307 triggers actions in response to errors to reduce errors, such as memory resource replacement at varying levels of granularity. The error handler 307 can be implemented in hardware, firmware, software, or a combination thereof. In one example, the error handler 307 is an SoC-level error handler. In one such example, the error handler 307 in turn notifies the end user about the error. Signal-based error reporting is also possible.

Thus, in accordance with examples described herein, the memory BIST tests executed in phases. In each phase, a small part of the memory is tested. In one example, the next region of the memory is tested in the phase that follows. This process can continue until the entire memory is tested. Once the entire memory is tested, the test can be repeated from the start of the memory. This runtime memory BIST testing can continue indefinitely, while the system is up and running.

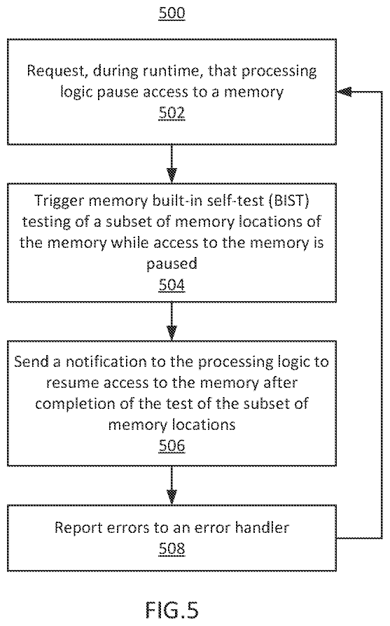

FIG. 4 illustrates an example of phases in which subsets of memory locations can be tested with memory BIST. The sequence illustrated in FIG. 4 starts with phase 1, in which a first subset of memory locations of a memory is tested with memory BIST testing. During phase 1 (e.g., during testing of the first subset of memory locations via memory BIST testing), processing logic temporarily stops accessing the memory. For example, referring to FIG. 3A, the processing logic 302 temporarily suspends access to the memory 312 during phase 1, and the runtime array BIST scheduler 306 triggers memory BIST testing of a small number of memory locations. In some examples, the suspension of access to the memory is referred to as a “micro pause,” which is a pause in memory access of sufficiently short duration so as to not significantly interrupt operation of the system, in one example. At the end of phase 1, testing of the memory is paused, and the processing logic can resume access to the memory.

After some predetermined time has passed, a second phase (phase 2) of testing begins, in which a second subset of memory locations of a memory is tested with memory BIST testing. In one example, a different subset of memory locations is tested in phase 2 than in phase 1. However, in some examples, some or even complete overlap of memory locations can occur in multiple phases. During phase 2 (e.g., during testing of the second subset of memory locations via memory BIST testing), processing logic stops accessing the memory. For example, referring to FIG. 3A, the processing logic 302 suspends access to the memory 312 during phase 2, and the array BIST scheduler 306 triggers memory BIST testing of another small number of memory locations. At the end of phase 2, testing of the memory is paused, and the processing logic can resume access to the memory.

In one example, this process continues for N phases with different subsets of memory locations until the entire memory (e.g., all memory locations that are eligible for testing) are tested. Thus, with a sequence of alternating testing phases (e.g., phase 1-phase N) and inter-phases, the entire memory can be thoroughly tested to prevent silent data errors without significant interruption of the system. According to examples, the length of the phases and/or interfaces is configurable (e.g., with one or more configuration registers, such as the register 304 of FIGS. 3A and 3C).

FIG. 5 is a flow chart of an example of a method 500 of testing a memory during runtime with memory BIST testing. In one example, the method 500 is performed by logic configured to schedule micro pauses and trigger testing of subsets of memory locations, such as the array BIST scheduler 206 of FIG. 2 or the array BIST scheduler 306 of FIGS. 3A and 3B. Runtime array BIST memory testing can be triggered automatically upon system start-up, in response to the setting of one or more enable or start bits, and/or in response to other triggers.

The method 500 begins with requesting, during runtime, that processing logic pause access to a memory, at block 502. For example, referring to FIG. 3A, the array BIST scheduler 306 sends a request to the processing logic 302 for the processing logic 302 to pause access to the memory 312. In one such example, the array BIST scheduler 306 asserts or de-asserts one or more signals (e.g., rta_bist_req) to indicate that a pause for testing is being requested (wherein asserting or de-asserting a signal refers to driving the signal to a logic zero or logic one, depending upon the agreed upon convention, to indicate information to the receiving logic). For ease of understanding, the following description will refer to the rta_bist_req signal as being asserted to indicate that a request is being made, however, other conventions can be used (e.g., the rta_bist_req signal transitioning to a logic zero or logic one can indicate a request, and/or more than one signal can be used to indicate a request). In one such example, although a single block of processing logic 302 is shown in FIG. 3A, the array BIST scheduler 306 can request that multiple blocks of processing logic or functional units pause access to the memory 312.

In one example, in response to the request to pause access to the memory (e.g., in response to assertion of the rta_bist_req signal), the processing logic 302 drains all queues. In one example, draining all queues involves executing any existing requests in the queues and stopping acceptance of new requests. In one such example, after the processing logic 302 has drained all queues, the processing logic 302 grants the pause for testing by asserting or de-asserting one or more signals to indicate to the array BIST scheduler 306 that the request has been granted (e.g., by asserting or de-asserting the rta_bist_gnt signal). For ease of understanding, the following description will refer to the rta_bist_gnt signal as being asserted to indicate that the request is granted, however, other conventions can be used (e.g., the rta_bist_gnt signal transitioning to a logic zero or logic one can indicate a grant, and/or more than one signal can be used to indicate a grant). In another example, the processing logic 302 grants the request before draining all queues (e.g., by pausing execution of existing requests in its queues). Thus, in one example, the array BIST scheduler requests or negotiates a micro pause from the processing logic in which a small subset of memory locations can be tested with memory BIST logic.

Referring again to FIG. 5, the method 500 involves triggering memory BIST testing of the subset of memory locations of the memory while access to the memory is paused, at block 504. For example, referring to FIG. 3A, in response to receiving the rta_bist_gnt signal from the processing logic 302 indicating that testing of the memory 312 can proceed, the array BIST scheduler 306 triggers memory BIST testing of a subset of memory locations of the memory 312. In another example, the array BIST scheduler 306 can trigger the testing after the passage of a predetermined time, rather than in response to a grant signal from the processing logic 302. Regardless of whether a grant signal, a predetermined time, or another mechanism is used, the array BIST scheduler 306 starts the memory BIST testing in accordance with an agreed upon trigger to prevent memory accesses to the memory 312 by the processing logic 302 while the memory BIST testing is underway.

In one example, triggering memory BIST testing of a subset of memory locations involves causing memory BIST control logic to perform tests on the subset of memory locations. For example, referring to FIG. 3A, the array BIST scheduler 306 causes or commands the memory BIST controller 310 to test the subset of memory locations via the memory BIST interface 308. Causing the memory BIST controller 310 to test the subset of memory locations can involve, for example, sending commands or otherwise asserting or de-asserting one or more signals to communicate one or more addresses of memory locations to be tested and/or a number of memory locations to be tested. In one example, the number of memory locations in the subset to be tested is based on a value stored in a register (e.g., the register 330 of FIG. 3C). The memory BIST controller 310 can then test the subset of memory locations in the memory 312 via the MBIST collars 311. For example, the memory BIST controller 310 can apply one or more patterns (e.g., write one or more patterns) to the subset of memory locations, and read back the values stored in those memory locations. The memory BIST controller 310 can then compare the written and read values and determine that an error has occurred if the read data does not have the expected value. If the memory BIST controller 310 detects an error, the memory BIST controller 310 can communicate the error to the array BIST scheduler 306. For example, the memory BIST controller 310 can send the address of the memory location(s) for which errors were detected via the memory BIST interface 308.

Referring again to FIG. 5, in response to completion of the memory BIST testing of the subset of memory locations, the method 500 involves sending an indication or notification to the processing logic to resume access to the memory, at block 506. For example, referring to FIG. 3A, the array BIST scheduler 306 receives an indication from the memory BIST controller 310 that the testing of the subset of memory locations is complete. The memory BIST controller 310 can then assert or de-assert one or more signals (e.g., de-assert the rta_bist_busy signal) to indicate that testing has completed. For ease of understanding, the following description will refer to the rta_bist_busy signal as being de-asserted to indicate that testing is complete, however, other conventions can be used (e.g., the rta_bist_busy signal transitioning to a logic zero or logic one can indicate testing is complete, and/or more than one signal can be used to indicate the completion of testing). In response to the notification that testing has completed, the processing logic 302 can resume access to the memory 312.

Referring again to FIG. 5, the method 500 continues with reporting errors to an error handler, at block 508. For example, referring to FIG. 3A, the array BIST scheduler 306 can indicate memory errors to an error handler 307 via sideband signaling (e.g., via a sideband router 309). The error handler 307 can then take action to mitigate the detected errors. After some predetermined time, the method is repeated by requesting, during runtime, that processing logic pause access to the memory in order to test the next subset of memory locations, at block 502. In one example, the operations in blocks 502-508 repeat until the entire memory is tested. Thus, in one example, the logic is to schedule the runtime testing of all memory locations of the memory that are eligible for testing in the multiple phases, wherein one of multiple subsets of memory locations is to be tested in each of the multiple phases. In one example, after completion of the runtime testing of all the memory locations of the memory that are eligible for testing, the logic is to repeat the runtime array BIST testing again from the beginning. In one such example, the runtime array BIST testing continues indefinitely during runtime until the testing is stopped and/or disabled.

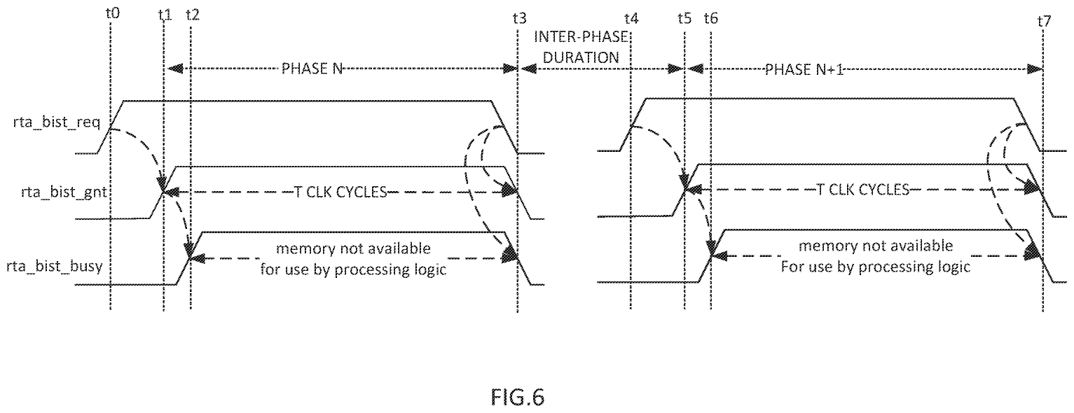

FIG. 6 illustrates a timing diagram of handshaking signals for runtime array BIST testing. For example, FIG. 6 illustrates an example timing diagram for the request (rta_bist_req), grant (rta_bist_gnt), and busy (rta_bist_busy) signals of FIG. 3A. Therefore, the following description of FIG. 6 refers to elements of FIG. 3A.

The timing diagram of FIG. 6 begins at time t0 when the runtime array BIST scheduler 306 asserts the rta_bist_req signal. In response to assertion of the request signal rta_bist_req, the processing logic 302 asserts the rta_bist_gnt signal at time t1 to indicate the request to pause access to the memory is granted. In one example, the processing logic 302 clears its queues of requests before asserting rta_bist_gnt. In response to assertion of the grant signal rta_bist_gnt, the runtime array BIST scheduler 306 triggers memory BIST testing of a subset of memory locations and asserts the rta_bist_busy signal at time t2 to indicate that the memory is not available for use by the processing logic. In response to completion of the memory BIST, the runtime array BIST scheduler 306 then de-asserts the rta_bist_busy signal at time t3 to indicate that the processing logic 302 can resume access to the memory 312. In the example illustrated in FIG. 6, the time from grant at time t1 until the busy signal is de-asserted at time t3 is phase N. The phase N in FIG. 6 has a duration of T clock cycles. As mentioned above with respect to FIG. 3C, in one example, the duration of a phase is configurable (e.g., by modifying the value stored in the register 330).

After a number of clock cycles has passed, the runtime array BIST scheduler 306 asserts the rta_bist_req signal again at time t4 to initiate the next phase of memory BIST testing. In response to assertion of the request signal rta_bist_req, the processing logic 302 asserts the rta_bist_gnt signal at time t5. In response to assertion of the grant signal rta_bist_gnt, the runtime array BIST scheduler 306 triggers memory BIST testing of a subset of memory locations, and asserts the rta_bist_busy signal at time t6 to indicate that the memory is not available for use by the processing logic. In response to completion of the memory BIST, the runtime array BIST scheduler 306 then de-asserts the rta_bist_busy signal at time t7 to indicate that the processing logic 302 can resume access to the memory 312. In the example illustrated in FIG. 6, the time from grant at time t5 until the busy signal is de-asserted at time t7 is phase N+1. The phase N+1 in FIG. 6 has the same duration as phase N of T clock cycles. However, as mentioned above with respect to FIG. 3C, in one example, the duration of a phase is configurable, which may include adjusting the phase duration between phases.

Thus, the timing diagram of FIG. 6 illustrates an example of handshaking signals between processing logic and runtime array BIST logic, such as the runtime array BIST scheduler 306 of FIGS. 3A and 3B. In other examples, different signals, additional signals, and/or different timing can be used to achieve periodic runtime array BIST testing.

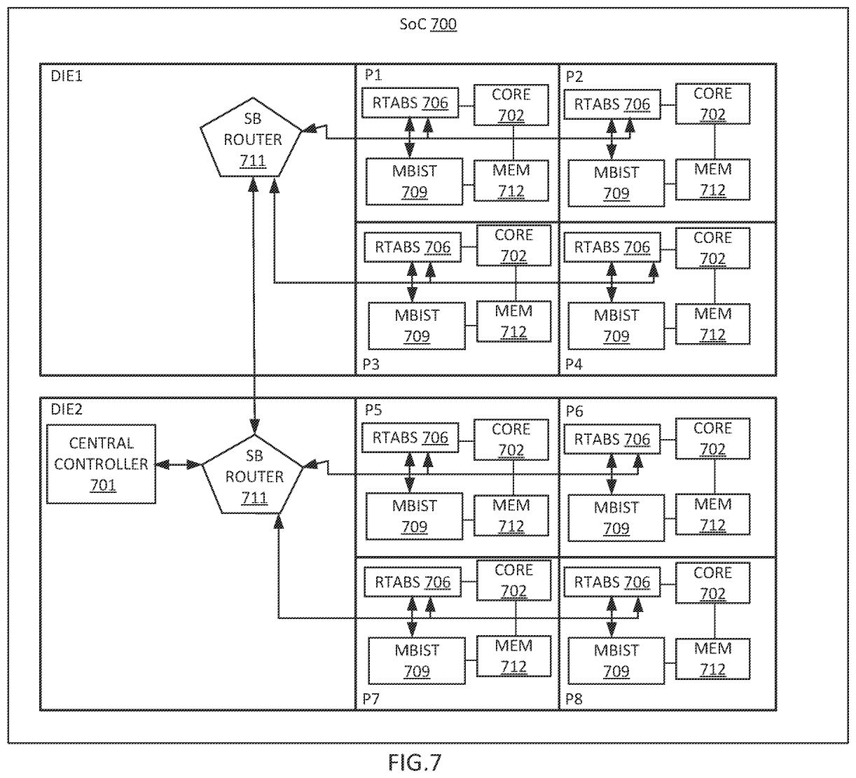

FIG. 7 illustrates a block diagram of an SoC in which runtime array BIST can be implemented. In one example, the SoC 700 is included in an automotive system. In FIG. 7, the SoC 700 includes two dies, die 1 and die 2. However, in another example, an SoC may include a single die or more than two dies. The SoC 700 is divided into and includes multiple partitions P1-P8. Although the SoC 700 is illustrated as including eight partitions, in other examples, an SoC can include fewer than or more than eight partitions. In one example, each of the partitions P1-P8 include partition memory (e.g., memory 712) and partition processing logic (e.g., core 702).

In the example illustrated in FIG. 7, each die includes its own sideband router 711. The sideband router 711 can be the same as, or similar to, the sideband router 309 of FIG. 3A. The SoC includes SoC-level control logic referred to as a central controller 701. In one example, the central controller 701 is a top level agent that includes a hardware interface with one or more of the sideband routers 711 and a software interface to communicated with software that runs on the platform. In one such example, the software includes an error handler that the central controller 701 sends detected errors to.

In addition to memory and processing resources, each of the partitions P1-P8 also includes memory BIST logic 709 and a runtime array BIST scheduler 706. In one example, the memory BIST logic 709 includes memory BIST interface logic, such as the memory BIST interface 308 of FIG. 3A and a memory BIST controller, such as the memory BIST controller 310 of FIG. 3A.

In one example, the runtime array BIST scheduler 706 of a partition can periodically trigger memory BIST testing of a subset of memory locations of that partition's memory 712. In another example, the array BIST scheduler 706 of a partition triggers memory BIST testing of that partition's memory 712 in response to a request from the central controller 701. Thus, in one such example, the central controller 701 can direct the runtime array BIST scheduler 706 in a partition to test its memory (e.g., periodically or in response to a request that the central controller 701 received from the platform software). In one example, the central controller 701 can request that all partitions perform runtime array BIST testing at the same time, or the central controller 701 can request that one or some of the partitions perform runtime array BIST testing.

In one example, the central controller 701 controls the pausing of the processing logic 702 of a partition to be tested and instructs the runtime array BIST scheduler 706 to trigger or execute the next phase of the runtime memory BIST algorithm. Errors can also be reported back to the central controller 701 (e.g., from the runtime array BIST scheduler 706 via the sideband routers 711). Thus, in one example, there is no need for any handshaking between the partition processing logic 702 and the runtime array BIST scheduler 706.

In one example, one or some partitions can be taken offline to perform exhaustive memory testing (e.g., POST) of that partition, while the remaining partitions are operating normally. In one such example, the central controller 701 can request that the partitions in a normal operation mode perform runtime array BIST testing, while one or some of the other partitions are offline for exhaustive testing. The central controller 701 can then take the next partition offline for exhaustive testing (e.g., in accordance with a round robin scheme), while the other partitions are in a normal operation mode. Regardless if partitions are occasionally taken offline for exhaustive testing, performing periodic runtime array BIST testing of memory can enable memory to be tested more frequently to detect errors earlier and prevent data corruption and safety issues.

In one example, techniques described herein involve an approach to execute memory tests periodically that is non-destructive (e.g., the testing does not corrupt the memory content) and during runtime (e.g., without taking the system out of an operational mode). Thus, in accordance with examples, the solution provides a path to minimize system performance impacts while reducing silent data errors, enabling high ASIL and SIL standards to be met.

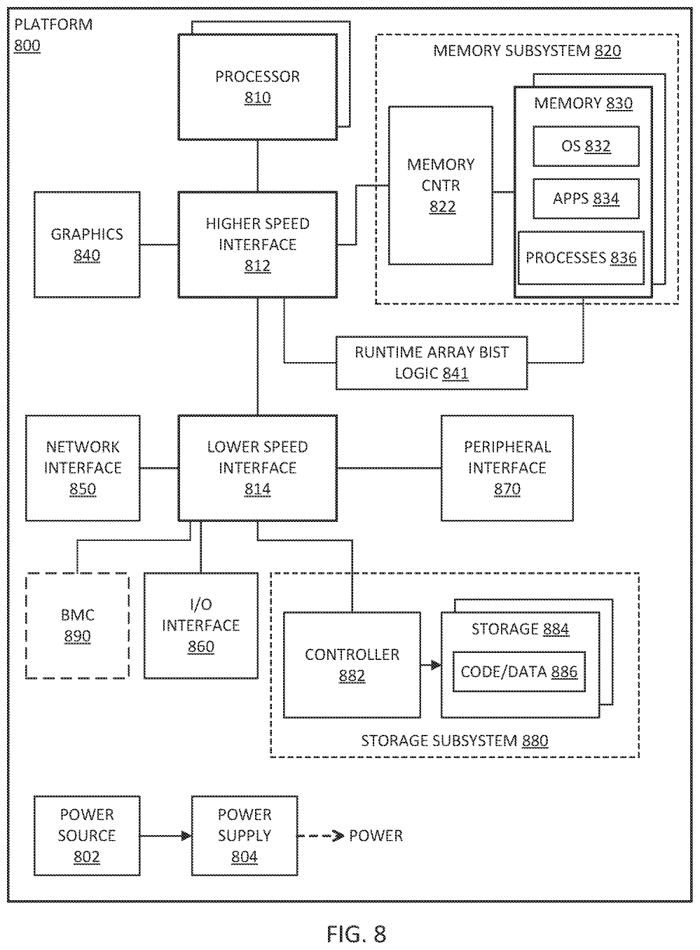

FIG. 8 illustrates a block diagram of an exemplary compute platform in which embodiments described and illustrated herein may be implemented. Compute platform 800 represents a computing device or computing system in accordance with any example described herein, and can be a server, laptop computer, desktop computer, or the like. The compute platform 800 can be, or include, the system 200 of FIG. 2, the system 300 of FIG. 3, or the SOC 700 of FIG. 7.

Compute platform 800 includes a processor 810, which provides processing, operation management, and execution of instructions for compute platform 800. Processor 810 can include any type of microprocessor, CPU, graphics processing unit (GPU), infrastructure processing unit (IPU), processing core, or other processing hardware to provide processing for compute platform 800, or a combination of processors. Processor 810 may also comprise an SoC or XPU. Processor 810 controls the overall operation of compute platform 800, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, compute platform 800 includes interface 812 coupled to processor 810, which can represent a higher speed interface or a high throughput interface for system components that needs higher bandwidth connections, such as memory subsystem 820 or graphics interface components 840. Interface 812 represents an interface circuit, which can be a standalone component or integrated onto a processor die. Where present, graphics interface 840 interfaces to graphics components for providing a visual display to a user of compute platform 800. In one example, graphics interface 840 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 840 generates a display based on data stored in memory 830 or based on operations executed by processor 810 or both.

Memory subsystem 820 represents the main memory of compute platform 800 and provides storage for code to be executed by processor 810, or data values to be used in executing a routine. Memory 830 of memory subsystem 820 may include one or more memory devices such as DRAM devices, read-only memory (ROM), flash memory, or other memory devices, or a combination of such devices. Memory 830 stores and hosts, among other things, operating system (OS) 832 to provide a software platform for execution of instructions in compute platform 800. Additionally, applications 834 can execute on the software platform of OS 832 from memory 830. Applications 834 represent programs that have their own operational logic to perform execution of one or more functions. Processes 836 represent agents or routines that provide auxiliary functions to OS 832 or one or more applications 834 or a combination. OS 832, applications 834, and processes 836 provide software logic to provide functions for compute platform 800. In one example, memory subsystem 820 includes memory controller 822, which is a memory controller to generate and issue commands to memory 830. It will be understood that memory controller 822 could be a physical part of processor 810 or a physical part of interface 812. For example, memory controller 822 can be an integrated memory controller, integrated onto a circuit with processor 810. The memory 830 and memory controller 822 can be in accordance with standards such as: DDR4 (Double Data Rate version 4), initial specification published in September 2012 by JEDEC (Joint Electronic Device Engineering Council). DDR4E (DDR version 4), LPDDR3 (Low Power DDR version 3, JESD209-3B, August 2013 by JEDEC), LPDDR4 (LPDDR version 4, JESD209-4, originally published by JEDEC in August 2014), WIO2 (Wide Input/Output version 2, JESD229-2 originally published by JEDEC in August 2014), HBM (High Bandwidth Memory, JESD325, originally published by JEDEC in October 2013), DDR5 (DDR version 5, JESD79-5A, published October, 2021), DDR version 6 (DDR6) (currently under draft development), LPDDR5, HBM2E, HBM3, and HBM-PIM, or others or combinations of memory technologies, and technologies based on derivatives or extensions of such specifications. The specification for LPDDR6 is currently under development. The JEDEC standards are available at www.jedec.org.

While not specifically illustrated, it will be understood that compute platform 800 can include one or more links, fabrics, buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses or other interconnections can include, for example, one or more of a system bus, a Peripheral Component Interconnect (PCI) bus, a HyperTransport or industry standard architecture (ISA) bus, a small computer system interface (SCSI) bus, a universal serial bus (USB), PCIe link, or an Institute of Electrical and Electronics Engineers (IEEE) standard 1394 bus.

In one example, compute platform 800 includes interface 814, which can be coupled to interface 812. Interface 814 can be a lower speed interface than interface 812. In one example, interface 814 represents an interface circuit, which can include standalone components and integrated circuitry. In one example, multiple user interface components or peripheral components, or both, couple to interface 814. Network interface 850 provides compute platform 800 the ability to communicate with remote devices (e.g., servers or other computing devices) over one or more networks. Network interface 850 can include an Ethernet adapter, wireless interconnection components, cellular network interconnection components, USB (universal serial bus), or other wired or wireless standards-based or proprietary interfaces. Network interface 850 can exchange data with a remote device, which can include sending data stored in memory or receiving data to be stored in memory.

In one example, compute platform 800 includes one or more I/O interface(s) 860. I/O interface(s) 860 can include one or more interface components through which a user interacts with compute platform 800 (e.g., audio, alphanumeric, tactile/touch, or other interfacing). Peripheral interface 870 can include any hardware interface not specifically mentioned above. Peripherals refer generally to devices that connect dependently to compute platform 800. A dependent connection is one where compute platform 800 provides the software platform or hardware platform or both on which operation executes, and with which a user interacts.

In one example, compute platform 800 includes storage subsystem 880 to store data in a nonvolatile manner. In one example, in certain system implementations, at least certain components of storage subsystem 880 can overlap with components of memory subsystem 820. Storage subsystem 880 includes storage device(s) 884, which can be or include any conventional medium for storing large amounts of data in a nonvolatile manner, such as one or more magnetic, solid state, or optical based disks, or a combination. Storage device(s) 884 holds code or instructions and data 886 in a persistent state (i.e., the value is retained despite interruption of power to compute platform 800). A portion of the code or instructions may comprise platform firmware that is executed on processor 810. Storage device(s) 884 can be generically considered to be a “memory,” although memory 830 is typically the executing or operating memory to provide instructions to processor 810. Whereas storage device(s) 884 is nonvolatile, memory 830 can include volatile memory (i.e., the value or state of the data is indeterminate if power is interrupted to compute platform 800). In one example, storage subsystem 880 includes controller 882 to interface with storage device(s) 884. In one example controller 882 is a physical part of interface 814 or processor 810 or can include circuits or logic in both processor 810 and interface 814.

Compute platform 800 may include an optional Baseboard Management Controller (BMC) 890 that is configured to effect the operations and logic corresponding to the flowcharts disclosed herein. BMC 890 may include a microcontroller or other type of processing element such as a processor core, engine or micro-engine, that is used to execute instructions to effect functionality performed by the BMC. Optionally, another management component (standalone or comprising embedded logic that is part of another component) may be used.

Power source 802 provides power to the components of compute platform 800. More specifically, power source 802 typically interfaces to one or multiple power supplies 804 in compute platform 800 to provide power to the components of compute platform 800. In one example, power supply 804 includes an AC to DC (alternating current to direct current) adapter to plug into a wall outlet. Such AC power can be renewable energy (e.g., solar power) power source 802. In one example, power source 802 includes a DC power source, such as an external AC to DC converter. In one example, power source 802 can include an internal battery or fuel cell source.

As discussed above, in some embodiment the processors illustrated herein may comprise Other Processing Units (collectively termed XPUs). Examples of XPUs include one or more of Graphic Processor Units (GPUs) or General Purpose GPUs (GP-GPUs), Tensor Processing Units (TPUs), Data Processing Units (DPUs), Infrastructure Processing Units (IPUs), Artificial Intelligence (AI) processors or AI inference units and/or other accelerators, FPGAs and/or other programmable logic (used for compute purposes), etc. While some of the diagrams herein show the use of CPUs, this is merely exemplary and non-limiting. Generally, any type of XPU may be used in place of a CPU in the illustrated embodiments. Moreover, as used in the following claims, the term “processor” is used to generically cover CPUs and various forms of XPUs.

The platform 800 includes runtime array BIST logic 841 coupled with the interface 812 and the memory 830. The runtime array BIST logic 841 includes logic to trigger and/or perform memory BIST on memory of the platform 800, such as the memory 830. In one example, the runtime array BIST logic 841 includes one or more of the runtime array BIST scheduler 306, the memory BIST interface 308, and the memory BIST controller 310 of FIG. 3A.

Examples of runtime memory BIST techniques follow.

Example 1: A device including: an interface to communicate with processing logic, the processing logic to access a memory, and logic to schedule runtime testing of the memory in multiple phases, including to: trigger memory built-in self-test (BIST) testing of a subset of memory locations in a phase, the processing logic to pause access to the memory during the phase, and in response to completion of the memory built-in self-test of the subset of the memory locations in the phase, send a notification to the processing logic to resume access to the memory.

Example 2: The device of example 1, wherein: execution of the memory BIST testing during runtime includes preservation of data stored at the subset of memory locations.

Example 3: The device of examples 1 or 2, wherein: a state of the subset of memory locations is the same before and after the memory BIST testing during runtime.

Example 4: The device of any of examples 1-3, wherein: the logic is to schedule the runtime testing of all memory locations of the memory that are eligible for testing in the multiple phases, wherein one of multiple subsets of memory locations is to be tested in each of the multiple phases.

Example 5: The device of any of examples 1-4, wherein: the processing logic is to resume access to the memory between successive phases of runtime testing.

Example 6: The device of any of examples 1-5, wherein: the logic to schedule the runtime testing is to: request, during runtime, that the processing logic pause access to the memory, and cause a memory BIST controller to test the subset of memory locations of the memory in the phase while the processing logic's access to the memory is paused.

Example 7: The device of any of examples 1-6, further including: a register to store a value to indicate a number of memory locations to test in one of the multiple phases, wherein the logic is to trigger the memory BIST testing in the phase for the number of memory locations indicated by the register.

Example 8: The device of any of examples 1-7, wherein: after completion of the runtime testing of all the memory locations of the memory that are eligible for testing, the logic is to repeat scheduling of the runtime testing of memory.

Example 9: The device of any of examples 1-8, wherein: the processing logic includes one or more of: a memory controller, a processor core, a partition of an SoC, an accelerator, and a cache controller.

Example 10: The device of any of examples 1-9, further including: a register to store a value to indicate a frequency at which to schedule the runtime testing, wherein the logic is to trigger the memory BIST testing in the multiple phases at the frequency indicated by the register.

Example 11: The device of any of examples 1-10, further including: a second interface with an error handler, wherein the logic is to report errors to an error handler via the second interface.

Example 12: An system on a chip (SoC) including: processing logic to access memory, and logic to schedule runtime testing of the memory in multiple phases, including to: trigger memory built-in self-test (BIST) testing of a subset of memory locations in a phase, the processing logic to pause access to the memory during the phase, and in response to completion of the memory built-in self-test of the subset of the memory locations in the phase, send a notification to the processing logic to resume access to the memory.

Example 13: The SoC of example 12, wherein: the SOC includes multiple partitions, each of the multiple partitions including partition memory and partition processing logic, and the logic is to: request that the partition processing logic of a partition pause access to the partition memory during runtime, and in response to completion of the memory built-in self-test of the subset of memory locations in the phase, send the notification to the partition processing logic to resume access to the partition memory.

Example 14: The SoC of examples 12 or 13, wherein: the logic is in accordance with any of examples 2-11.

Example 15: A method of testing a memory during runtime, the method including: triggering memory built-in self-test (BIST) testing of subsets of memory locations of the memory during runtime in multiple testing phases in which access to the memory is paused, and in response to completion of the memory BIST of a subset of memory locations in a testing phase, cause access to the memory to resume between successive testing phases.

Example 16: The method of example 15, wherein: triggering the memory BIST testing for a subset of memory locations includes: sending a request during runtime to a functional module to pause access to the memory, and causing a memory BIST controller to test the subset of memory locations of the memory while access to the memory is paused during runtime.

Example 17: The method of examples 15 or 16, wherein: execution of the memory BIST testing during runtime includes preservation of data stored at the subset of memory locations.

Example 18: A non-transitory machine-readable medium having instructions stored thereon configured to be executed on one or more processors to perform a method in accordance with any of examples 15-17.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

The hardware design embodiments discussed above may be embodied within a semiconductor chip and/or as a description of a circuit design for eventual targeting toward a semiconductor manufacturing process. In the case of the later, such circuit descriptions may take of the form of a (e.g., VHDL or Verilog) register transfer level (RTL) circuit description, a gate level circuit description, a transistor level circuit description or mask description or various combinations thereof. Circuit descriptions are typically embodied on a computer readable storage medium (such as a CD-ROM or other type of storage technology).

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

What is claimed is:

1. A device comprising:
an interface to communicate with processing logic, the processing logic to access a memory; and
logic to schedule runtime testing of the memory in multiple phases, including to:
trigger memory built-in self-test (BIST) testing of a subset of memory locations in a phase, the processing logic to pause access to the memory during the phase; and
in response to completion of the memory built-in self-test of the subset of the memory locations in the phase, send a notification to the processing logic to resume access to the memory.

2. The device of claim 1, wherein:
execution of the memory BIST testing during runtime includes preservation of data stored at the subset of memory locations.

3. The device of claim 1, wherein:
a state of the subset of memory locations is the same before and after the memory BIST testing during runtime.

4. The device of claim 1, wherein:
the logic is to schedule the runtime testing of all memory locations of the memory that are eligible for testing in the multiple phases, wherein one of multiple subsets of memory locations is to be tested in each of the multiple phases.

5. The device of claim 1, wherein:
the processing logic is to resume access to the memory between successive phases of runtime testing.

6. The device of claim 1, wherein:
the logic to schedule the runtime testing is to:
request, during runtime, that the processing logic pause access to the memory, and
cause a memory BIST controller to test the subset of memory locations of the memory in the phase while the processing logic's access to the memory is paused.

7. The device of claim 1, further comprising:
a register to store a value to indicate a number of memory locations to test in one of the multiple phases;
wherein the logic is to trigger the memory BIST testing in the phase for the number of memory locations indicated by the register.

8. The device of claim 1, wherein:
after completion of the runtime testing of all the memory locations of the memory that are eligible for testing, the logic is to repeat scheduling of the runtime testing of memory.

9. The device of claim 1, wherein:
the processing logic includes one or more of: a memory controller, a processor core, a partition of an SoC, an accelerator, and a cache controller.

10. The device of claim 1, further comprising:
a register to store a value to indicate a frequency at which to schedule the runtime testing;
wherein the logic is to trigger the memory BIST testing in the multiple phases at the frequency indicated by the register.

11. The device of claim 1, further comprising:
a second interface with an error handler;
wherein the logic is to report errors to an error handler via the second interface.

12. A system on a chip (SoC) comprising:
processing logic to access memory; and
logic to schedule runtime testing of the memory in multiple phases, including to:
trigger memory built-in self-test (BIST) testing of a subset of memory locations in a phase, the processing logic to pause access to the memory during the phase; and
in response to completion of the memory built-in self-test of the subset of the memory locations in the phase, send a notification to the processing logic to resume access to the memory.

13. The SoC of claim 12, wherein:
the SOC includes multiple partitions, each of the multiple partitions including partition memory and partition processing logic; and
the logic is to:
request that the partition processing logic of a partition pause access to the partition memory during runtime, and
in response to completion of the memory built-in self-test of the subset of memory locations in the phase, send the notification to the partition processing logic to resume access to the partition memory.

14. The SoC of claim 12, wherein:
execution of the memory BIST testing during runtime includes preservation of data stored at the subset of memory locations.

15. The SoC of claim 12, wherein:
a state of the subset of memory locations is the same before and after the memory BIST testing during runtime.

16. The SoC of claim 12, wherein:
the logic is to schedule the runtime testing of all memory locations of the memory that are eligible for testing in the multiple phases, wherein one of multiple subsets of memory locations is to be tested in each of the multiple phases.

17. The SoC of claim 12, wherein:
the processing logic is to resume access to the memory between successive phases of the runtime testing.

18. A non-transitory machine-readable medium having instructions stored thereon configured to be executed on one or more processors to perform a method comprising:
triggering memory built-in self-test (BIST) testing of subsets of memory locations of the memory during runtime in multiple testing phases in which access to the memory is paused; and
in response to completion of the memory BIST of a subset of memory locations in a testing phase, cause access to the memory to resume between successive testing phases.

19. The non-transitory machine-readable medium of claim 18, wherein:
triggering the memory BIST testing for a subset of memory locations includes:
sending a request during runtime to a functional module to pause access to the memory, and
causing a memory BIST controller to test the subset of memory locations of the memory while access to the memory is paused during runtime.

20. The non-transitory machine-readable medium of claim 18, wherein:
execution of the memory BIST testing during runtime includes preservation of data stored at the subset of memory locations.
